(19) United States
(12) Patent Application Publication
(10) Pub. No.: US 2023/0104518 A1
(43) Pub. Date: Apr. 6, 2023

(54) METHOD AND SYSTEM FOR PRE-PROCESSING GEOMETRIC MODEL DATA OF 3D MODELING SOFTWARE FOR DEEP LEARNING

(71) Applicant: National Kaohsiung University of Science and Technology, Kaohsiung (TW)

(72) Inventors: I-Chen WU, Kaohsiung (TW); Chi-Chang LIU, Kaohsiung (TW); Chih-Hsiung CHANG, Kaohsiung (TW)

(21) Appl. No.: 17/953,669

(22) Filed: Sep. 27, 2022

Related U.S. Application Data
(60) Provisional application No. 63/251,843, filed on Oct. 4, 2021.

(51) Int. Cl. G06F 30/27; G06F 30/12

(52) U.S. Cl. CPC G06F 30/27; G06F 30/12

(57) ABSTRACT

A method for pre-processing geometric model data of a 3D modeling software for deep learning includes steps of: determining a size of a virtual grid that is visualized as a cube based on a smallest value of dimension among values of dimension of objects; generating an empty tensor that is visualized as a cuboid consisting of the virtual grids; assigning an initial value to each of the virtual grids of the empty tensor; replacing the initial value of each of those of the virtual grids with a pre-determined identification attribute value that corresponds uniquely to the property of the corresponding one of the at least one geometric object, so as to generate a 3D geometric model tensor to be used as an input for deep learning; and saving the 3D geometric model tensor in a database in a predefined format.

### CROSS-REFERENCE TO RELATED APPLICATION

This application claims priority to U.S. Provisional Patent Application No. 63/251,843, filed on Oct. 4, 2021.

### FIELD

The disclosure relates to a method and a system for data processing, and more particularly to a method and a system for pre-processing geometric model data of a 3D modeling software for deep learning.

### BACKGROUND

A three-dimensional (3D) modeling software, such as Autodesk Revit, AECOSim Building Designer, ArchiCAD, Vectorworks Architect, Tekla, etc., is used for creating, modifying, revising and managing digital 3D models. Each 3D model is a digital representation of at least a part of a place (e.g., a building, a factory, etc.), and includes geometric model data related to physical properties and/or functional features of objects (such as doors, windows, pipelines, furniture or equipment, etc.) in the place.

For example, conventional geometric model data may include a set of coordinates, a size, orientation and some descriptive information for each object so that the geometric model data may establish spatial relationship among the objects. Furthermore, in the case that the conventional geometric model data is a 3D image composed of plural pixels and is read using traditional computer graphics methods or technologies, hundreds of millions of pixels should be read. Therefore, in general, the geometric model data has quite a large file size and is relatively complex. When deep learning module is used to extract features and recognize the objects from the geometric model data for further application, feature extraction takes a long time.

In some cases, the geometric model data would first be converted to 2D format, and then input into the deep learning module for image classification. However, in 2D format, details of the objects (such as pipelines) may be represented by single line drawings, which results in inaccurate image classification results.

### SUMMARY

Therefore, an object of the disclosure is to provide a method for pre-processing geometric model data of a 3D modeling software for deep learning that can alleviate at least one of the drawbacks of the prior art.

According to the disclosure, the method for pre-processing geometric model data of a three-dimensional (3D) modeling software for deep learning is implemented by a processor and includes the following steps.

The geometric model data is related to presenting a 3D model that is created using the 3D modeling software and contains data related to at least one geometric object in the 3D model. The 3D model has a predetermined spatial coordinate system having a first axis, a second axis and a third axis that are mutually perpendicular to each other. Each of the at least one geometric object is assigned a property.

In a step, the processor determines a size of a virtual grid that is visualized as a cube based on a smallest value of dimension among values of dimension of the at least one geometric object along the first, the second and the third axes.

In another step, the processor generates an empty tensor that is visualized as a cuboid consisting of a plurality of the virtual grids. The cuboid has a size that is determined based on a largest value of dimension among the values of dimension of the at least one geometric object along the first, the second and the third axes.

In yet another step, the processor assigns an initial value to each of the virtual grids of the empty tensor.

In still another step, for those of the virtual grids of the empty tensor that each correspond to one of the at least one geometric object, the processor replaces the initial value of each of those of the virtual grids with a pre-determined identification attribute value that corresponds uniquely to the property of the corresponding one of the at least one geometric object, so as to generate a 3D geometric model tensor to be used as an input for deep learning.

In one other step, the processor saves the 3D geometric model tensor in a database in a predefined format.

Another object of the disclosure is to provide a system for pre-processing geometric model data of a 3D modeling software for deep learning that can alleviate at least one of the drawbacks of the prior art.

According to the disclosure, the system includes a processor and a storage device having stored therein the 3D modeling software, the geometric model data, and a pre-processing module that is used to pre-process the geometric model data to obtain a 3D geometric model tensor to be used as an input for deep learning.

The processor is electrically connected to the storage device, and when executing the pre-processing module, is configured to perform the method for pre-processing geometric model data of a 3D modeling software for deep learning as described above.

### BRIEF DESCRIPTION OF THE DRAWINGS

Other features and advantages of the disclosure will become apparent in the following detailed description of the embodiment(s) with reference to the accompanying drawings, of which:

FIG. 1 is a block diagram of a system for processing geometric model data of a 3D modeling software according to an embodiment of the disclosure;

FIG. 2 is a schematic diagram illustrating a 3D model that is created using the 3D modeling software according to an embodiment of the disclosure;

FIG. 3 is a flow chart of an embodiment of a method for processing geometric model data of the 3D modeling software;

FIG. 4 is a schematic diagram illustrating an empty tensor that is generated based on the 3D model and that is visualized as a cuboid consisting of virtual grids; and

FIG. 5 is a schematic diagram of a 3D geometric model tensor related to the 3D model.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

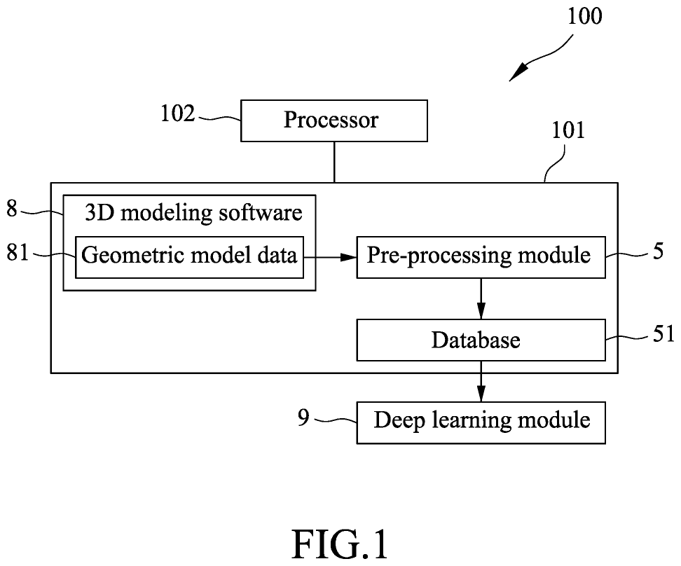

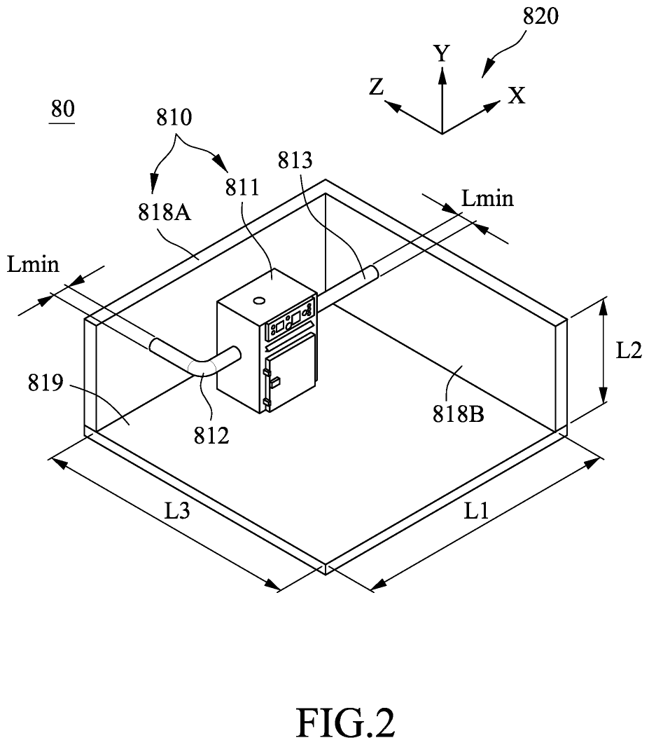

Referring to FIGS. 1 and 2, an embodiment of a system 100 is configured to implement a method for processing geometric model data 81 of a 3D modeling software 8, and includes a storage device 101 and a processor 102 electrically connected to the storage device 101.

In this embodiment, the storage device 101 may be embodied using one or more of a hard disk, a solid-state drive (SSD) and other non-transitory storage media. The processor 102 is, for example, a single core processor, a multi-core processor, a dual-core mobile processor, a microprocessor, a micro-controller, a digital signal processor (DSP), a field programmable gate array (FPGA), an application specific integrated circuit (ASIC), or a radio frequency integrated circuit (RFIC), etc.

The storage device 101 stores a pre-processing module 5 and the 3D modeling software 8. The 3D modeling software 8 may be a building information modeling software, such as Autodesk Revit®, AECOSim Building Designer, ArchiCAD, Vectorworks Architect, Tekla, etc.

A 3D model 80 is created using the 3D modeling software 8 and has a predetermined spatial coordinate system having a first axis, a second axis and a third axis that are mutually perpendicular to each other, and the geometric model data 81 is related to presenting the 3D model 80. In the case that the 3D modeling software 8 is Autodesk Revit®, the geometric model data 81 is saved in the storage device 101 in the form of a “*.rvt” file. The geometric model data 81 contains data related to at least one geometric object in the 3D model 80. Each geometric object may be assigned a coordinate set in the predetermined spatial coordinate system, a size, orientation and a property.

For example, the geometric model data 81 contains data related to a plurality of geometric objects 810 in the 3D model 80 in a left-handed coordinate system 820 (which serves as the predetermined spatial coordinate system), as shown in FIG. 2. In this example, the geometric objects 810 include an apparatus object 811, an inlet tube object 812, an outlet tube object 813, two wall objects 818A and 818B, and a floor object 819. Said “apparatus,” “inlet tube,” “outlet tube,” “wall” and “floor” proceeding the term “object” are defined by properties of the plurality of geometric objects 810. The left-handed coordinate system 820 has an X axis, a Y axis and a Z axis that are mutually perpendicular to each other. In other examples, the predetermined spatial coordinate system may be a right-handed coordinate system.

The pre-processing module 5 is used to pre-process the geometric model data 81 to obtain a 3D geometric model tensor (detailed below) that is to be used as an input to a deep learning module 9, such as a VGG (Visual Geometry Group) module, and may be implemented as instructions stored on the storage device 101. In some embodiments, the pre-processing module 5 may be a plug-in to the 3D modeling software 8. When reading and executing the instructions, the processor 102 is configured to perform the method for processing the geometric model data 81.

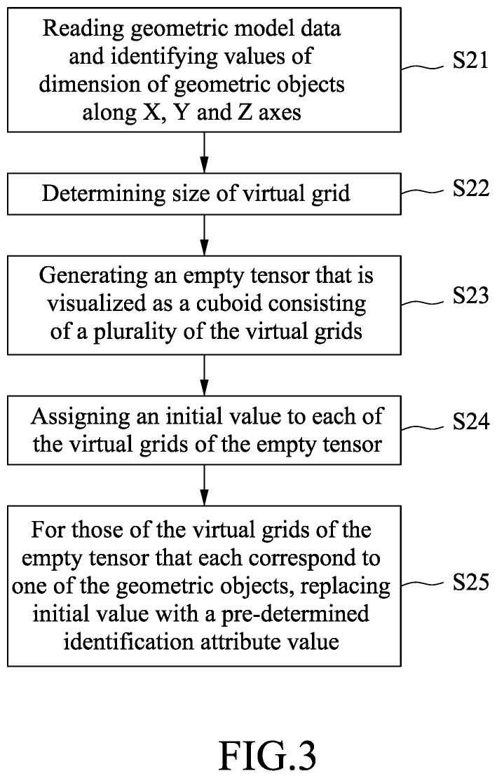

Referring to FIG. 3, the method includes the following steps.

In step S21, the processor 102 reads the coordinate set, the size, the orientation and the property of each of the plurality of geometric objects 810 from the geometric model data 81. The processor 102 further identifies and/or calculates, for each of the plurality of geometric objects 810, values of dimension (also simply “length”) thereof respectively along the X, Y and Z axes.

For example, as shown in Table_A1 below, each of the plurality of geometric objects 810 has a first minimum length along the X axis, a second minimum length along the Y axis, and a third minimum length along the Z axis. The unit for the numbers listed in Table_A1 may vary in different cases, for example, in inches, feet, meters or centimeters. Furthermore, in this embodiment, for the geometric object having the property of “wall” or “floor,” a thickness (typically, the smallest value of dimension) of the geometric object 810 in the geometric model data 81 is ignored by default. Thus, the value of dimension of the wall object 818A along the Z axis, the value of dimension of the wall object 818B along the X axis, and the value of dimension of the floor object 819 along the Y axis are all ignored (shown as “--” in Table_A1).

TABLE_A1

| | object | object | object | object | object | object |
|---|---|---|---|---|---|---|
| | 811 | 812 | 813 | 818A | 818B | 819 |
| first | 12 | 3 | 24 | 60 | — | 60 |
| min_L | | | | | | |
| second | 15 | 3 | 3 | 24 | 24 | — |
| min_L | | | | | | |
| third | 9 | 3 | 3 | — | 60 | 60 |
| min_L | | | | | | |

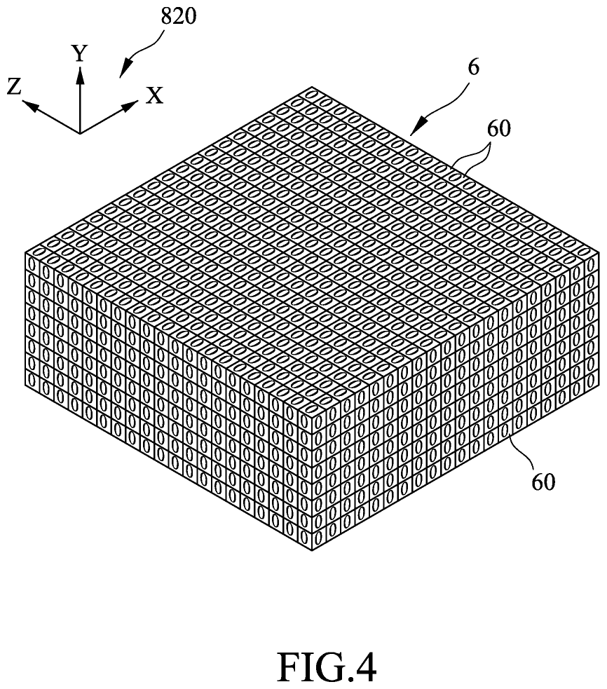

In step S22, the processor 102 determines a size of a virtual grid 60 (as shown in FIG. 4). The virtual grid 60 is visualized as a cube having a side length equal to a smallest value of dimension of the plurality of geometric objects 810. Following the example of FIG. 2 and Table_A1, “3” is the smallest value of dimension among all of the values of dimension of the plurality of geometric objects 810 along the X, Y and Z axes. Thus, the processor 102 determines the side length of the virtual grid 60 to be equal to “3”. The virtual grid 60 is used as the smallest unit to re-represent the 3D model 80 in the following processing.

In step S23, the processor 102 generates an empty tensor 6 that is visualized as a cuboid consisting of a plurality of the virtual grids 60 as shown in FIG. 4. The cuboid has a size based on the largest values of dimension of the plurality of geometric objects 810 along the X, Y and Z axes. In detail, similar to Table_A1, each of the plurality of geometric objects 810 has a first maximum length along the X axis, a second maximum length along the Y axis, and a third maximum length along the Z axis as shown in Table_A2 below. Thus, the cuboid may have a length equal to 60 (which is the largest value of dimension among all of the values of dimension of the plurality of geometric objects 810 along the X axis, hereinafter L1), a height equal to 24 (which is the largest value of dimension among all of the values of dimension of the plurality of geometric objects 810 along the Y axis, hereinafter L2), and a width equal to 60 (which is the largest value of dimension among all of the values of dimension of the plurality of geometric objects 810 along the Z axis, hereinafter L3). In other words, the plurality of geometric objects 810 as a whole have a first maximum value of dimension along the X axis that serves as the length of the cuboid of the empty tensor 6, a second maximum value of dimension along the Y axis that serves as the height of the cuboid of the empty tensor 6, and a third maximum value of dimension along the Z axis that serves as the width of the cuboid of the empty tensor 6.

TABLE_A2

| | object | object | object | object | object | object |
|---|---|---|---|---|---|---|
| | 811 | 812 | 813 | 818A | 818B | 819 |
| first | 12 | 9 | 24 | 60 | — | 60 |
| max_L | | | | | | |
| second | 15 | 3 | 3 | 24 | 24 | — |
| max_L | | | | | | |
| third | 9 | 12 | 3 | — | 60 | 60 |
| max_L | | | | | | |

Since the cuboid of the empty tensor 6 is composed of the virtual grids 60, and the side length of each of the virtual grids 60 is “3”, the values of dimension of the plurality of geometric objects 810 along the X, Y and Z axes can be expressed by a number of the virtual grids 60 along the X, Y and Z axes, as shown in Table B below. With respect to each of the values of dimension of each geometric object 810, the number of the virtual grids 60 along the corresponding one of the X, Y and Z axes is obtained by dividing the value of dimension of the geometric object 810 along the corresponding one of the X, Y and Z axes by the side length of the virtual grid 60. In the case that the value of dimension of the geometric object 810 is not divisible by the side length of the virtual grid 60, the processor 102 rounds the quotient up to an integer unconditionally. Thus, in terms of the number of virtual grids 60, the cuboid of the empty tensor 6 is composed of 3,200 (=20*8*20) virtual grids 60.

TABLE_B

| | object | object | object | object | object | object |
|---|---|---|---|---|---|---|
| | 811 | 812 | 813 | 818A | 818B | 819 |
| first | 4 | 3 | 8 | 20 | — | 20 |
| max_L | | | | | | |
| first | 4 | 1 | 8 | 20 | — | 20 |
| min_L | | | | | | |
| second | 5 | 1 | 1 | 8 | 8 | — |
| max_L | | | | | | |
| second | 5 | 1 | 1 | 8 | 8 | — |
| min_L | | | | | | |
| third | 3 | 4 | 1 | — | 20 | 20 |
| max_L | | | | | | |
| third | 3 | 1 | 1 | — | 20 | 20 |
| min_L | | | | | | |

It should be noted that the above Table_A1, Table_A2 and Table B are for illustrative purposes only, and that generating tables is not necessary and the processor 102 can perform the steps S21 and S23 without any table.

In step S24, the processor 102 assigns an initial value (e.g., zero) to each of the virtual grids 60 of the empty tensor 6.

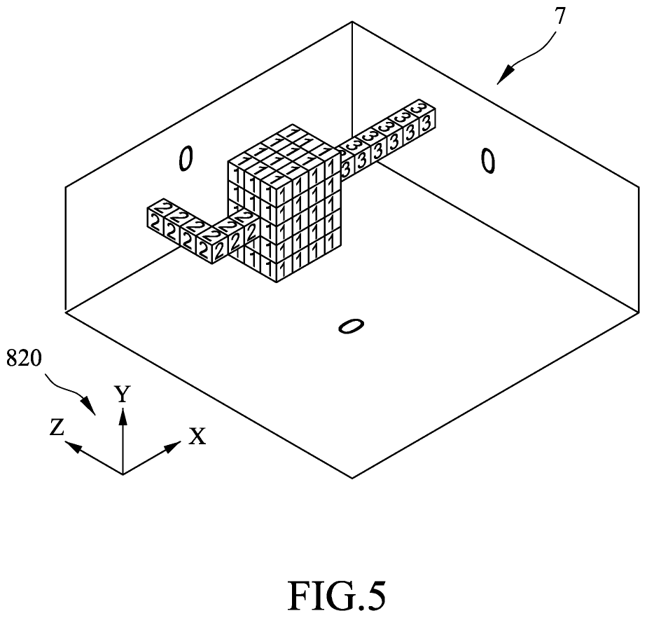

In step S25, for those of the virtual grids 60 of the empty tensor 6 that each correspond to one of the plurality of geometric objects 810, the processor 102 replaces the value of each of those of the virtual grids 60 with a pre-determined identification attribute value that corresponds uniquely to the property of the corresponding one of the plurality of geometric objects 810. For example, as shown in FIG. 5, the processor 102 actually only replaces the values of the virtual grids 60 that correspond to the apparatus object 811, the inlet tube object 812 and the outlet tube object 813, since the thicknesses of the wall objects 818A and 818B and the floor object 819 are ignored (i.e., none of the virtual grids 60 corresponds to the wall objects 818A and 818B or the floor object 819 in the empty tensor 6). Specifically, the processor 102 replaces the value of each of the virtual grids 60 that corresponds to the apparatus object 811 with “1,” replaces the value of each of the virtual grids 60 that corresponds to the inlet tube object 812 with “2,” and replaces the value of each of the virtual grids 60 that corresponds to the outlet tube object 813 with “3”. In this way, a 3D geometric model tensor 7 related to the 3D model 80 is generated as shown in FIG. 5. For illustrative purposes, only three “0's” are shown in the 3D geometric model tensor 7 of FIG. 5, to schematically represent the many virtual grids 60 that still have the initial value of “0”. In this embodiment, the 3D geometric model tensor 7 may be, but not limited to, a tensor of ASCII (American Standard Code for Information Interchange) format, and can be converted into a string, and thus can generally be read and used directly.

In step S25, the processor 102 saves the 3D geometric model tensor 7 in a database 51 in a predefined format, such as “*.txt,” “*.json,” “*.csv,” “*.xls,” etc. In this embodiment, the database 51 is stored in the storage device 101. In other embodiments, the database 51 may be stored in another device such as a cloud storage. The 3D geometric model tensor 7 can be further used as an input to the deep learning module 9.

It is noted that since the 3D model 80 is generally composed of hundreds of millions of pixels in computer vision, it is too large for a deep learning module 9 to run properly when the 3D model 80 is not converted into the 3D geometric model tensor 7. In this case, the 3D model 80 needs to be divided into thousands of data pieces for input into the deep learning module 9 (for example, VGG 16) for training. Therefore, when training one of the data pieces of the 3D model 80 having 200,000 pixels takes 100 seconds, it may take more than hundreds of thousands of seconds to complete the training of the 3D model 80 fully.

On the other hand, when the 3D model 80 is converted into the 3D geometric model tensor 7, there are merely a few thousand grids that need to be input into the deep learning module 9 for training. Normally, it takes about 10 to 20 seconds to complete the training with the same deep learning module 9.

Thus, by means of the pre-processing module 5, the geometric model data 81 can be converted into a form of tensor, i.e., the 3D geometric model tensor 7, through the processes of generating the virtual grids 60 and the empty tensor 6. The 3D geometric model tensor 7 can efficiently represent a huge amount of data contained in the geometric model data 81, and record the descriptive content such as the properties of the plurality of geometric objects 810 using different identification attribute values. Accordingly, the 3D geometric model tensor 7 can be accessed directly and input into the deep learning module 9 directly for feature extraction and further applications, without having to be converted to a 2D format for image classification nor having to be divided into thousands of pieces. When the deep learning module 9 reads the 3D geometric model tensor 7 to extract features, it takes a relatively short time because the amount of data is significantly reduced. Thus, the method for processing the geometric model data 81 can simplify the process and increase speed and accuracy.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A method for pre-processing geometric model data of a three-dimensional (3D) modeling software for deep learning, the geometric model data being related to presenting a 3D model that is created using the 3D modeling software and containing data related to at least one geometric object in the 3D model, the 3D model having a predetermined spatial coordinate system that has a first axis, a second axis and a third axis which are mutually perpendicular to each other, each of the at least one geometric object being assigned a property, the method to be implemented by a processor and comprising steps of:
determining a size of a virtual grid that is visualized as a cube based on a smallest value of dimension among values of dimension of the at least one geometric object along the first, the second and the third axes;
generating an empty tensor that is visualized as a cuboid consisting of a plurality of the virtual grids, the cuboid having a size that is determined based on a largest value of dimension among the values of dimension of the at least one geometric object along the first, the second and the third axes;
assigning an initial value to each of the virtual grids of the empty tensor;
for those of the virtual grids of the empty tensor that each correspond to one of the at least one geometric object, replacing the initial value of each of those of the virtual grids with a pre-determined identification attribute value that corresponds uniquely to the property of the corresponding one of the at least one geometric object, so as to generate a 3D geometric model tensor to be used as an input for deep learning; and
saving the 3D geometric model tensor in a database in a predefined format.

2. The method of claim 1, the at least one geometric object as a whole having a first maximum value of dimension along the first axis, a second maximum value of dimension along the second axis, and a third maximum value of dimension along the third axis,
wherein the step of generating an empty tensor includes using the first maximum value of dimension to serve as a length of the cuboid, using the second maximum value of dimension to serve as a height of the cuboid, and using the third maximum value of dimension to serve as a width of the cuboid.

3. The method of claim 2, wherein the step of determining a virtual grid includes determining the smallest value of dimension of the at least one geometric object, and making a side length of the virtual grid equal to the smallest value of dimension.

4. The method of claim 2, wherein the step of generating an empty tensor includes, with respect to each of the values of dimension of the at least one geometric object, dividing the value of dimension by the side length of the virtual grid, and, in the case that the value of dimension of the at least one geometric object is not divisible by the side length of the virtual grid, rounding a quotient up to an integer unconditionally.

5. A system for pre-processing geometric model data of a 3D modeling software for deep learning, the geometric model data being related to presenting a 3D model that is created using the 3D modeling software and containing data related to at least one geometric object in the 3D model, the 3D model having a predetermined spatial coordinate system that has a first axis, a second axis and a third axis which are mutually perpendicular to each other, each of the at least one geometric object being assigned a property, the system comprising:
a storage device having stored therein the 3D modeling software, the geometric model data, and a pre-processing module; and
a processor electrically connected to said storage device, and when executing the pre-processing module being configured to
determine a size of a virtual grid that is visualized as a cube based on a smallest value of dimension among values of dimension of the at least one geometric object along the first, the second and the third axes,
generate an empty tensor that is visualized as a cuboid consisting of a plurality of the virtual grids, the cuboid having a size that is determined based on a largest value of dimension among the values of dimension of the at least one geometric object along the first, the second and the third axes;
assign an initial value to each of the virtual grids of the empty tensor;
for those of the virtual grids of the empty tensor that each correspond to one of the at least one geometric object, replace the initial value of each of those of the virtual grids with a pre-determined identification attribute value that corresponds uniquely to the property of the corresponding one of the at least one geometric object, so as to generate a 3D geometric model tensor to be used as an input for deep learning; and
save the 3D geometric model tensor in a database in a predefined format.
